(19) United States
(12) Patent Application Publication
(10) Pub. No.: US 2002/0173157 A1
(43) Pub. Date: Nov. 21, 2002

(54) Dual damascene method employing composite low dielectric constant dielectric layer having intrinsic etch stop characteristics

(75) Inventors: Weng Chang, Taipei (TW); Tien-I Bao, Hsin-Chu (TW); Yaoyi Chen, Taipei (TW); Syun-Ming Jang, Hsin-Chu (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 09/821,554

(22) Filed: Mar. 29, 2001

(51) Int. Cl. H01L 21/311

(52) U.S. Cl. 438/700

(57) ABSTRACT

Within a dual damascene method for forming a contiguous patterned conductor interconnect and patterned conductor stud layer within a corresponding trench contiguous with a corresponding via formed through a dielectric layer formed of a comparatively low dielectric constant dielectric material, the dielectric layer is, prior to dual damascene etching, formed of a patterned first dielectric layer having formed thereupon a blanket second dielectric layer. The patterned first dielectric layer is formed of a first dielectric material and the blanket second dielectric layer is formed of a second dielectric material, where each of the first dielectric material and the second dielectric material has a dielectric constant of less than about 4.0, but wherein the first dielectric material serves as an intrinsic etch stop when dual damascene etching the dielectric layer.

### BACKGROUND OF THE INVENTION

1. Field of the Invention

The present invention relates generally to methods for forming patterned conductor layers separated by patterned dielectric layers within microelectronics fabrications. More particularly, the present invention relates to dual damascene methods for forming patterned conductor layers separated by patterned dielectric layers within microelectronics fabrications.

2. Description of the Related Art

Microelectronic fabrications are formed from microelectronic substrates over which are formed patterned microelectronic conductor layers which are separated by microelectronic dielectric layers.

As microelectronic fabrication integration levels have increased and microelectronic device and patterned microelectronic conductor layer dimensions have decreased, it has become increasingly common within the art of microelectronic fabrication to employ interposed between the patterns of patterned microelectronic conductor layers within microelectronic fabrications microelectronic dielectric layers formed of comparatively low dielectric constant dielectric materials. For the purposes of the present disclosure, comparatively low dielectric constant dielectric materials are intended as dielectric materials having a dielectric constant of preferably less than about 4.0, more preferably less than about 3.5 and yet more preferably less than about 3.0. For comparison purposes, microelectronic dielectric layers which are conventionally formed employing denser silicon oxide dielectric materials, denser silicon nitride dielectric materials and/or denser silicon oxynitride dielectric, which may be deposited employing chemical vapor deposition (CVD) methods, plasma enhanced chemical vapor deposition (PECVD) methods and physical vapor deposition (PVD) methods, typically have a comparatively high dielectric constant in a range of greater than about 4.0 to about 8.0.

Microelectronic dielectric layers formed of comparatively low dielectric constant dielectric materials are desirable interposed between the patterns of patterned microelectronic conductor layers within microelectronic fabrications insofar as such microelectronic dielectric layers formed from such comparatively low dielectric constant dielectric materials assist in providing microelectronic fabrications with enhanced microelectronic fabrication speed, attenuated patterned microelectronic conductor layer parasitic capacitance and attenuated patterned microelectronic conductor layer cross-talk.

In conjunction with the use of comparatively low dielectric constant dielectric materials when forming microelectronic dielectric layers interposed between the patterns of patterned microelectronic conductor layers within microelectronic fabrications, it has also become common in the art of microelectronic fabrication to employ when forming patterned microelectronic conductor layers within microelectronic fabrications dual damascene methods. As is understood by a person skilled in the art, within a dual damascene method there is generally formed into a trench defined by a patterned second dielectric layer overlapping and contiguous with a via defined by a patterned first dielectric layer formed beneath the patterned second dielectric layer a single contiguous patterned conductor interconnect and patterned conductor stud layer while employing a single chemical mechanical polish (CMP) planarizing method.

Dual damascene methods are also desirable in the art of microelectronic fabrication insofar as there may often be reduced when forming a patterned conductor interconnect layer contacting a patterned conductor stud layer within a microelectronic fabrication a number of process steps needed for forming the patterned conductor interconnect layer contacting the patterned conductor stud layer within the microelectronic fabrication while employing a dual damascene method, in comparison with other feasible microelectronic fabrication methods.

While dual damascene methods when employed in conjunction with dielectric layers formed employing comparatively low dielectric constant dielectric materials are thus desirable in the art of microelectronic fabrication, dual damascene methods when employed in conjunction with dielectric layers formed employing comparatively low dielectric constant dielectric materials are nonetheless not entirely without problems in the art of microelectronic fabrication. In that regard, dual damascene methods when employed in conjunction with dielectric layers formed employing comparatively low dielectric constant dielectric materials often require additional microelectronic fabrication layers and microelectronic fabrication processing, such as but not limited to additional microelectronic fabrication etch stop layers and additional microelectronic fabrication etch stop processing, when fabricating while employing a dual damascene method a contiguous patterned conductor interconnect and patterned conductor stud layer within a corresponding trench contiguous with a corresponding via through a dielectric layer formed employing a comparatively low dielectric constant dielectric material within a microelectronic fabrication.

It is thus desirable in the art of microelectronic fabrication to provide dual damascene methods for forming within microelectronic fabrications contiguous patterned conductor interconnect and patterned conductor stud layers within corresponding trenches contiguous with corresponding vias formed in turn formed through dielectric layers formed of comparatively low dielectric constant dielectric materials, with enhanced microelectronic fabrication processing efficiency.

It is towards the foregoing object that the present invention is directed.

Various dual damascene methods have been disclosed in the art of microelectronics fabrication for forming, with desirable properties within microelectronic fabrications, contiguous patterned conductor interconnect and patterned conductor stud layers within corresponding trenches contiguous with corresponding vias formed through dielectric layers within microelectronic fabrications.

For example, Yu et al., in U.S. Pat. No. 6,004,883, discloses a dual damascene method for forming within a patterned dielectric layer within a microelectronic fabrication a contiguous patterned conductor interconnect and patterned conductor stud layer within a corresponding trench contiguous with a corresponding via defined within the patterned dielectric layer within the microelectronic fabrication while avoiding the use of an etch stop layer when defining within the patterned dielectric layer the corresponding trench contiguous with the corresponding via. To realize the foregoing result, the dual damascene method employs when defining within the patterned dielectric layer the corresponding trench contiguous with the corresponding via a multilayer dielectric layer comprising: (1) a patterned first dielectric layer defining the via, where the patterned first dielectric layer is formed of a first dielectric material which is not susceptible to etching within an oxygen containing plasma; and (2) a blanket second dielectric layer formed upon the patterned first dielectric layer and filling the via, where the blanket second dielectric layer is formed of a second dielectric material which is susceptible to etching within the oxygen containing plasma.

In addition, Lee et al., in U.S. Pat. No. 6,096,655, also discloses a dual damascene method for forming within a patterned dielectric layer within a microelectronic fabrication a contiguous patterned conductor interconnect and patterned conductor stud layer within a corresponding trench contiguous with a corresponding via defined within the patterned dielectric layer while avoiding the use of an etch stop layer when defining within the patterned dielectric layer the corresponding trench contiguous with the corresponding via. To realize the foregoing result, the dual damascene method employs when defining within the patterned dielectric layer the corresponding trench contiguous with the corresponding via a sacrificial pillar layer which defines the corresponding via and a sacrificial bridge layer which defines the corresponding trench, and where portions of the patterned dielectric layer are formed after forming the sacrificial pillar layer and the sacrificial bridge layer.

Finally, Subramanian et al., in U.S. Pat. No. 6,127,089, discloses in part a dual damascene method for forming within a patterned dielectric layer within a microelectronic fabrication a contiguous patterned conductor interconnect and patterned conductor stud layer within a corresponding trench contiguous with a corresponding via defined within the patterned dielectric layer while providing for enhanced process efficiency when defining within the patterned dielectric layer the corresponding trench contiguous with the corresponding via. To realize the foregoing result, the dual damascene method employs when defining within the patterned dielectric layer the corresponding trench contiguous with the corresponding via a photoimaged patterned photoimageable material layer formed of a photoimageable material, such as a silicon rich acrylic photopolymer material, which upon exposure to an oxygen containing plasma incident to etching the patterned dielectric layer is transformed into a hard mask layer.

Desirable in the art of microelectronic fabrication are additional dual damascene methods for forming within microelectronic fabrications contiguous patterned conductor interconnect and patterned conductor stud layers within corresponding trenches contiguous with corresponding vias formed in turn through dielectric layers formed of comparatively low dielectric constant dielectric materials, with enhanced microelectronic fabrication processing efficiency.

It is towards the foregoing object that the present invention is directed.

### SUMMARY OF THE INVENTION

A first object of the present invention is to provide a dual damascene method for forming within a microelectronic fabrication a contiguous patterned conductor interconnect and patterned conductor stud layer within a corresponding trench contiguous with a corresponding via formed in turn formed through a dielectric layer within the microelectronic fabrication.

A second object of the present invention is to provide a dual damascene method in accord with the first object of the present invention, wherein the dielectric layer is formed of a comparatively low dielectric constant dielectric material.

A third object of the present invention is to provide a dual damascene method in accord with the first object of the present invention and the second object of the present invention, wherein the dual damascene method provides for enhanced microelectronic fabrication processing efficiency.

A fourth object of the present invention is to provide a dual damascene method in accord with the first object of the present invention, the second object of the present invention and the third object of the present invention, wherein the dual damascene method is readily commercially implemented.

In accord with the objects of the present invention, there is provided by the present invention a method for forming an aperture through a dielectric layer. To practice the method of the present invention, there is first provided a substrate. There is then formed upon the substrate a patterned first dielectric layer formed of a first dielectric material having a first dielectric constant of less than about 4.0, the patterned first dielectric layer defining a via. There is then formed upon the patterned first dielectric layer and filling the via a blanket second dielectric layer formed of a second dielectric material having a second dielectric constant of less than about 4.0. There is then formed over the blanket second dielectric layer a patterned mask layer which defines the location of a trench to be formed through the blanket second dielectric layer, where an areal dimension of the trench is greater than and at least in part overlapping an areal dimension of the via. There is then etched, while employing the patterned mask layer in conjunction with an anisotropic etch method, the blanket second dielectric layer to form therethrough an aperture comprising: (1) the trench; and (2) at least a portion of the via, where the patterned first dielectric layer serves as an intrinsic etch stop within the anisotropic etch method.

There is provided by the present invention a dual damascene method for forming within a microelectronic fabrication a contiguous patterned conductor interconnect and patterned conductor stud layer within a corresponding trench contiguous with a corresponding via formed in turn formed through a dielectric layer formed of a comparatively low dielectric constant dielectric material, with enhanced microelectronic fabrication processing efficiency.

The present invention realizes the foregoing object by employing when forming an aperture through a dielectric layer in accord with a dual damascene method and further in accord with the present invention, a composite dielectric layer comprising: (1) a patterned first dielectric layer formed of a first dielectric material having a first dielectric constant of less than about 4.0, the patterned first dielectric layer defining a via; and (2) a blanket second dielectric layer formed upon the patterned first dielectric layer and filling the via, the blanket second dielectric layer being formed of a second dielectric material having a second dielectric constant of less than about 4.0; where (3) the patterned first dielectric layer serves as an intrinsic etch stop within an anisotropic etch method employed for etching the blanket second dielectric layer to form therethrough an aperture comprising: (1) a trench; contiguous with (2) at least a portion of the via.

The method of the present invention is readily commercially implemented. The present invention employs methods and materials which are otherwise generally known in the art of microelectronics fabrication, but employed within the context of a novel materials selection and process ordering to provide the present invention. Since it is at least in part a novel materials selection and process ordering which provides at least in part the present invention, rather than the existence of methods and materials which provides the present invention, the method of the present invention is readily commercially implemented.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3 and FIG. 4 show a series of schematic cross-sectional diagrams illustrating the results of progressive stages in forming within a microelectronics fabrication, and in accord with a preferred embodiment of the present invention, a pair of contiguous patterned conductor interconnect and patterned conductor stud layers within a pair of corresponding trenches contiguous with a pair of corresponding vias formed through a dielectric layer formed of a comparatively low dielectric constant dielectric material, while employing a dual damascene method in accord with the present invention.

### DESCRIPTION OF THE PREFERRED EMBODIMENTS

The present invention provides a dual damascene method for forming within a microelectronic fabrication a contiguous patterned conductor interconnect and patterned conductor stud layer within a corresponding trench contiguous with a corresponding via formed in turn formed through a dielectric layer formed of a comparatively low dielectric constant dielectric material, with enhanced microelectronic fabrication processing efficiency.

The present invention realizes the foregoing object by employing when forming an aperture through a dielectric layer in accord with a dual damascene method and further in accord with the present invention, a composite dielectric layer comprising: (1) a patterned first dielectric layer formed of a first dielectric material having a first dielectric constant of less than about 4.0, the patterned first dielectric layer defining a via; and (2) a blanket second dielectric layer formed upon the patterned first dielectric layer and filling the via, the blanket second dielectric layer being formed of a second dielectric material having a second dielectric constant of less than about 4.0; where (3) the patterned first dielectric layer serves as an intrinsic etch stop within an anisotropic etch method employed for etching the blanket second dielectric layer to form therethrough an aperture comprising: (1) a trench; contiguous with (2) at least a portion of the via.

Although the present invention provides particular value for forming within semiconductor integrated circuit microelectronic fabrications, and within trenches contiguous with vias formed through dielectric layers formed of comparatively low dielectric constant dielectric materials, corresponding contiguous patterned conductor interconnect and patterned conductor stud layers to thus provide dual damascene structures within the semiconductor integrated circuit microelectronic fabrication, the present invention may also be employed for analogous dual damascene structures within microelectronic fabrications including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

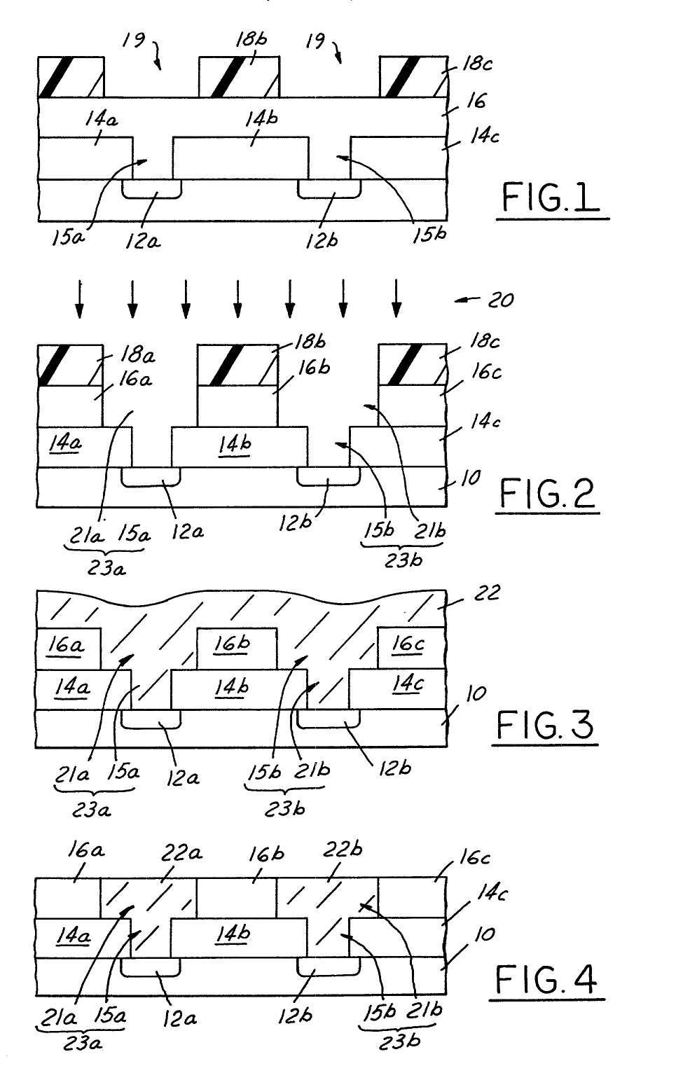

Referring now to FIG. 1 to FIG. 4, there is shown a series of schematic cross-sectional diagrams illustrating the results of progressive stages in forming within a microelectronics fabrication, and in accord with a preferred embodiment of the present invention, a pair of contiguous patterned conductor interconnect and patterned conductor stud layers within a pair of corresponding trenches contiguous with a pair of corresponding vias formed through a dielectric layer formed of a comparatively low dielectric constant dielectric material, while employing a dual damascene method in accord with the present invention.

Shown in FIG. 1 is a schematic cross-sectional diagram of the microelectronic fabrication at an early stage in its fabrication in accord with the preferred embodiment of the present invention.

Shown in FIG. 1, in a first instance, is a substrate 10 having formed therein a pair of contact regions 12a and 12b.

Within the preferred embodiment of the present invention with respect to the substrate 10, the substrate 10 may consist of or comprise a substrate employed within a microelectronic fabrication selected from the group including but not limited to integrated circuit microelectronics fabrications, ceramic substrate microelectronic fabrications, solar cell optoelectronic microelectronic fabrications, sensor image array optoelectronic microelectronic fabrications and display image array optoelectronic microelectronic fabrications.

Although not specifically illustrated within the schematic cross-sectional diagram of FIG. 1, and as indicated above, the substrate 10 may consist of the substrate alone as employed within the microelectronic fabrication, or in the alternative, and also as indicated above, the substrate 10 may comprise the substrate as employed within the microelectronic fabrication, where under such alternative circumstances the substrate as employed within the microelectronic fabrication may have any of several additional microelectronic layers formed thereupon or thereover as are conventional within the microelectronic fabrication within which is employed the substrate. Similarly with the substrate alone as employed within the microelectronic fabrication, such additional microelectronic layers may be formed of microelectronic materials including but not limited to microelectronic conductor materials, microelectronic semiconductor materials and microelectronic dielectric materials.

Similarly, and although also not specifically illustrated within the schematic cross-sectional diagram of FIG. 1, the substrate 10, typically and preferably, but not exclusively, when the substrate 10 consists of or comprises a semiconductor substrate as employed within a semiconductor integrated circuit microelectronic fabrication, has formed therein and/or thereupon microelectronic devices as are conventional within the microelectronic fabrication within which is employed the substrate. Such microelectronic devices may include, but are not limited to resistors, transistors, diodes and capacitors.

Within the preferred embodiment of the present invention with respect to the contact regions 12a and 12b formed within the substrate 10, the contact regions 12a and 12b formed within the substrate 10 will typically and preferably be either conductor contact regions or semiconductor contact regions within the microelectronics fabrication within which is employed the substrate 10. Typically and preferably, within the present invention when the substrate 10 consists of a semiconductor substrate alone as employed within a semiconductor integrated circuit microelectronics fabrication, the contact regions 12a and 12b are semiconductor substrate contact regions which are typically employed when forming semiconductor devices within the semiconductor substrate.

Similarly, within the present invention when the contact regions 12a and 12b are conductor contact regions, they may be formed of conductor materials including but not limited to metal, metal alloy, doped polysilicon (having a dopant concentration of greater than about 1E18 dopant atoms per cubic centimeter) and polycide (doped polysilicon/metal silicide stack) conductor materials. Further, and in particular when the contact regions 12a and 12b are conductor contact regions formed of a copper metal or copper metal alloy conductor material, there is typically and preferably employed appropriate barrier layers either surrounding the pair of contact regions 12a and 12b or otherwise isolating the pair of contact region 12a and 12b from adjoining layers within the microelectronic fabrication whose schematic cross-sectional diagram is illustrated in FIG. 1 with which the copper metal or copper metal alloy conductor material within the contact region 12a and 12b might otherwise interdiffuse.

Shown also within FIG. 1, and formed upon the substrate 10, is a series of patterned first dielectric layers 14a, 14b and 14c which define a pair of vias 15a and 15b which in turn access the pair of contact regions 12a and 12b.

Within the preferred embodiment of the present invention with respect to the series of patterned first dielectric layers 14a, 14b and 14c, the series of patterned first dielectric layers 14a, 14b and 14c is formed of a first dielectric material having a first dielectric constant preferably less than about 4.0, more preferably less than about 3.5 and yet more preferably less than about 3.0, thus constituting a comparatively low dielectric constant dielectric material in accord with the present invention.

Within the preferred embodiment of the present invention with respect to the comparatively low dielectric constant dielectric material from which is formed the series of patterned first dielectric layers 14a, 14b and 14c, the comparatively low dielectric constant dielectric material from which is formed the series of patterned first dielectric layers 14a, 14b and 14c may be selected from the group including but not limited to: (1) organic polymer spin-on-polymer (SOP) dielectric materials (such as but not limited to polyimide organic polymer spin-on-polymer (SOP) dielectric materials, polyarylene ether organic polymer spin-on-polymer (SOP) dielectric materials, parylene organic polymer spin-on-polymer (SOP) dielectric materials and fluorinated analogs thereof); (2) spin-on-glass (SOG) dielectric materials (typically such as but not limited to hydrogen silsesquioxane spin-on-glass (SOG) dielectric materials, carbon bonded hydrocarbon silsesquioxane spin-on-glass (SOG) dielectric materials, and carbon bonded fluorocarbon silsesquioxane spin-on-glass (SOG) dielectric materials); (3) amorphous carbon dielectric materials (such as but not limited to amorphous carbon, hydrogenated amorphous carbon and fluorinated amorphous carbon); (4) diamond like carbon dielectric materials (such as but not limited to diamond like carbon, hydrogenated diamond like carbon and fluorinated diamond like carbon; (5) carbonaceous silicate glass dielectric materials (such as may be obtained from incomplete oxidation of organosilane carbon and silicon source materials); (6) fluorosilicate glass (FSG) dielectric materials; and (7) aerogel (air or insulating gas entrained) microporous dielectric materials.

Typically and preferably, each of the series of patterned first dielectric layers 14a, 14b and 14c is formed to a thickness of from about 4000 to about 10000 angstroms. Similarly, each of the first vias 15a and 15b typically and preferably has a linewidth of from about 0.2 to about 0.5 microns.

Also shown in FIG. 1, and formed upon the series of patterned first dielectric layers 14a, 14b and 14c and portions of the contact regions 12a and 12b exposed within the corresponding pair of vias 15a and 15b, while completely filling the pair of vias 15a and 15b, is a blanket second dielectric layer 16.

Within the preferred embodiment of the present invention with respect to the blanket second dielectric layer 16, the blanket second dielectric layer 16 is formed of a second dielectric material also having a dielectric constant of preferably less than about 4.0, more preferably less than about 3.5 and yet more preferably less than about 3.0, and where the second dielectric material is selected from the same group of dielectric materials as the first dielectric material, but wherein the first dielectric material and the second dielectric material are selected such that the first dielectric material serves intrinsically as an etch stop within an anisotropic etch method, and in particular an anisotropic plasma etch method, which is subsequently employed for etching the blanket second dielectric layer 16. Thus, typically and preferably, with respect to a particular choice of first dielectric material, second dielectric material and anisotropic etch method, in order to provide intrinsic etch stop characteristics there will be exhibited for the second dielectric material with respect to the first dielectric material within the anisotropic etch method an etch selectivity of preferably at least about 20:1, more preferably at least about 30:1 and yet more preferably at least about 50:1.

Typically and preferably, the blanket second dielectric layer 16 is formed to a thickness of from about 4000 to about 7000 angstroms upon the series of patterned first dielectric layers 14a, 14b and 14c and exposed portions of the pair of contact regions 12a and 12b, while completely filling the pair of vias 15a and 15b.

Finally, there is also shown in FIG. 1 formed upon the blanket second dielectric layer 16 a series of patterned photoresist layers 18a, 18b and 18c.

Within the preferred embodiment of the present invention with respect to the series of patterned photoresist layers 18a, 18b and 18c, the series of patterned photoresist layers 18a, 18b and 18c may be formed from any of several photoresist materials as are generally known in the art of microelectronic fabrication, including but not limited to photoresist materials selected from the general groups of photoresist materials including but not limited to positive photoresist materials and negative photoresist materials. Preferably, each of the series of patterned photoresist layers 18a, 18b and 18c is formed to a thickness of from about 7000 to about 15000 angstroms.

Although not completely illustrated within the schematic cross-sectional diagram of FIG. 1, the patterned photoresist layers 18a, 18b and 18c define a pair of first apertures 19a and 19b leaving exposed a pair of portions of the blanket second dielectric layer 16 of areal dimension greater than an areal dimension of a corresponding via 15a or 15b, while simultaneously at least partially overlapping the areal dimension of the corresponding via 15a or 15b. More preferably, and as is partially illustrated within the schematic cross-sectional diagram of FIG. 1, the areal dimension of each aperture 19a and 19b within the pair of apertures 19a and 19b completely overlaps and encompasses the areal dimension of a corresponding via 15a or 15b within the pair of vias 15a and 15b.

Although not specifically illustrated within the schematic cross-sectional diagram of FIG. 1, and as is understood by a person skilled in the art, under circumstances within the present invention where the blanket second dielectric layer 16 is formed of a second dielectric material which when etched within an anisotropic etchant will also etch the series of patterned photoresist layers 18a, 18b and 18c, there of necessity will typically and preferably also be employed within the present invention, and formed interposed between the blanket second dielectric layer 16 and the series of patterned photoresist layers 18a, 18b and 18c, a blanket hard mask layer from which is subsequently formed a series of patterned hard mask layers. The positioning and use of such a blanket hard mask layer is illustrated more specifically within Yu et al., as cited within the Description of the Related Art, all of which related art is incorporated herein fully by reference. Such a blanket hard mask layer may frequently be formed of a dielectric material analogous or equivalent to the dielectric material from which is formed the series of patterned first dielectric layers 14a, 14b and 14c.

Referring now to FIG. 2, there is shown a schematic cross-sectional diagram illustrating the results of further processing of the microelectronic fabrication whose schematic cross-sectional diagram is illustrated in FIG. 1.

Shown in FIG. 2 is a schematic cross-sectional diagram of a microelectronic fabrication otherwise equivalent to the microelectronic fabrication whose schematic cross-sectional diagram is illustrated in FIG. 1, but wherein the blanket second dielectric layer 16 has been patterned to form a series of patterned second dielectric layers 16a, 16b and 16c, while employing the series of patterned photoresist layers 18a, 18b and 18c as an etch mask layer, in conjunction with an etching plasma 20. As is illustrated within the schematic cross-sectional diagram of FIG. 1, and in accord with the above, when patterning the blanket second dielectric layer 16 to form the series of patterned second dielectric layers 16a, 16b and 16c, the series of patterned first dielectric layers 14a, 14b and 14c serves as an intrinsic etch stop and there is thus formed upon patterning of the blanket second dielectric layer 16 to form the series of patterned second dielectric layers 16a, 16b and 16c a pair of second apertures 23a and 23b comprising: (1) a pair of trenches 21a and 21b defined by the series of patterned second dielectric layers 16a, 16b and 16c contiguous with; (2) at least a pair of portions of the pair of vias 15a and 15b.

Insofar as within the present invention the series of patterned first dielectric layers 14a, 14b and 14c serve as an intrinsic etch stop in conjunction with the etching plasma 20 which is intended as an anisotropic etching plasma, and significant to the present invention, is the absence within the present invention interposed between the series of patterned first dielectric layers 14a, 14b and 14c and the blanket second dielectric layer 16 of a series of extrinsic (i.e., independently formed) etch stop layers, as is otherwise generally employed within dual damascene methods as employed when fabricating microelectronic fabrications.

Referring now to FIG. 3, there is shown a schematic cross-sectional diagram illustrating the results of further processing of the microelectronic fabrication whose schematic cross-sectional diagram is illustrated in FIG. 2.

Shown in FIG. 3 is a schematic cross-sectional diagram of a microelectronic fabrication otherwise equivalent to the microelectronic fabrication whose schematic cross-sectional diagram is illustrated in FIG. 2, but wherein, in a first instance, the series of patterned photoresist layers 18a, 18b and 18c has been stripped from the corresponding series of patterned second dielectric layers 16a, 16b and 16c.

Within the preferred embodiment of the present invention, the series of patterned photoresist layers 18a, 18b and 18c may be stripped from the series of patterned second dielectric layers 16a, 16b and 16c while employing photoresist stripping methods as are conventional in the art of microelectronic fabrication, such photoresist stripping methods including but not limited to wet chemical photoresist stripping methods and dry plasma photoresist stripping methods.

Shown also within the schematic cross-sectional diagram of FIG. 3 after having stripped from the series of patterned second dielectric layers 16a, 16b and 16c the series of patterned photoresist layers 18a, 18b and 18c is the presence of a blanket conductor layer 22 formed upon exposed portions of the patterned second dielectric layers 16a, 16b and 16c, the patterned first dielectric layers 14a, 14b and 14c and the pair of contact regions 12a and 12b, while completely filling the pair of trenches 21a and 21b defined by the series of patterned second dielectric layers 16a, 16b and 16c contiguous with the pair of vias 15a and 15b defined by the series of patterned first dielectric layers 14a, 14b and 14c which in the aggregate form the pair of second apertures 23a and 23b.

Within the preferred embodiment of the present invention, the blanket conductor layer 22 may be formed employing methods and materials analogous or equivalent to the methods and materials employed for forming the contact regions 12a and 12b, under conditions where the contact regions 12a and 12b are conductor contact regions. Typically and preferably, the blanket conductor layer 22 is formed to a thickness of from about 4000 to about 7000 angstroms. Similarly, when the blanket conductor layer 22 is formed of copper metal or copper metal alloy conductor material, it will also include an appropriate barrier material layer to avoid detrimental interdiffusion with adjoining layers.

Referring now to FIG. 4, there is shown a schematic cross-sectional diagram illustrating the results of further processing of the microelectronic fabrication whose schematic cross-sectional diagram is illustrated in FIG. 3.

Shown in FIG. 4 is a schematic cross-sectional diagram of a microelectronic fabrication otherwise equivalent to the microelectronic fabrication whose schematic cross-sectional diagram is illustrated in FIG. 3, but wherein the blanket conductor layer 22 has been planarized to form a pair of contiguous patterned conductor interconnect and patterned conductor stud layers 22a and 22b within the pair of corresponding trenches 21a and 21b contiguous with the pair of corresponding vias 15a and 15b which in the aggregate form the pair of second apertures 23a and 23b.

Within the preferred embodiment of the present invention, the blanket conductor layer 22 may be patterned to form the pair of contiguous patterned conductor interconnect and patterned conductor stud layers 22a and 22b while employing chemical mechanical polish (CMP) planarizing methods as are otherwise conventional in the art of microelectronic fabrication.

Upon forming the microelectronic fabrication whose schematic cross-sectional diagram is illustrated in FIG. 4, there is provided within a microelectronic fabrication a pair of contiguous patterned conductor interconnect and patterned conductor stud layers within a pair of corresponding trenches contiguous with a pair of corresponding vias formed in turn formed through a dielectric layer formed of a comparatively low dielectric constant dielectric material, with enhanced microelectronic fabrication processing efficiency.

The present invention realizes the foregoing object by employing when forming an aperture through a dielectric layer in accord with a dual damascene method and further in accord with the present invention, a composite dielectric layer comprising: (1) a patterned first dielectric layer formed of a first dielectric material having a first dielectric constant of less than about 4.0, the patterned first dielectric layer defining a via; and (2) a blanket second dielectric layer formed upon the patterned first dielectric layer and filling the via, the blanket second dielectric layer being formed of a second dielectric material having a second dielectric constant of less than about 4.0; where (3) the patterned first dielectric layer serves as an intrinsic etch stop within an anisotropic etch method employed for etching the blanket second dielectric layer to form therethrough an aperture comprising: (1) a trench; contiguous with (2) at least a portion of the via.

### EXAMPLES

In order to demonstrate viability of the present invention, there was formed upon a series of semiconductor substrates a series of dielectric layers formed of comparatively low dielectric constant dielectric materials. The series of dielectric layers formed of the series of comparatively low dielectric constant dielectric materials consisted of: (1) a dielectric layer formed of a fluorinated polyarylene ether (FLARE) spin-on-polymer (SOP) dielectric material available from Honeywell; (2) a dielectric layer formed of a hydrogen silsesquioxane (HSQ) spin-on-glass (SOG) dielectric material available from Dow Corning; (3) a dielectric layer formed of a hydrogenated diamond like carbon (DLC) dielectric material formed employing a chemical vapor deposition (CVD) method employing a methane carbon and hydrogen source material; and (4) a dielectric layer formed of a fluorosilicate glass (FSG) dielectric material formed employing a chemical vapor deposition (CVD) method employing a carbon tetrafluoride fluorine source material and a tetra-ethylorthosilicate (TEOS) silicon source material. Each of the dielectric layers was formed to a thickness of about 4000 angstroms upon a corresponding semiconductor substrate.

For comparison purposes, there was also prepared a semiconductor substrate having formed thereupon a dielectric layer formed of a silicon nitride dielectric material formed employing a chemical vapor deposition (CVD) method, as is otherwise generally conventionally employed as an etch stop layer within a dual damascene method.

Each of the dielectric layers was then etched within a fluorine containing plasma etch method in order to determine a comparative etch rate of each of the dielectric materials. The fluorine containing plasma etch method also employed: (1) a reactor chamber pressure of about 60 Mtorr; (2) a radio frequency power of about 1000 watts; (3) a substrate (and dielectric layer) temperature of about 30 degrees centigrade; (4) a carbon tetrafluoride flow rate of about 30 standard cubic centimeters per minute (sccm); (5) a trifluoromethane flow rate of about 20 standard cubic centimeters per minute (sccm); and (6) an argon flow rate of about 200 standard cubic centimeters per minute (sccm).

The dielectric constants of the dielectric materials and the comparative etch rates of the dielectric layers are reported below in Table I.

TABLE I

| Dielectric Matl | Dielectric Const | Rel Etch Rate |
|---|---|---|
| SOP-FLARE | 2.8 | 300 |
| SOG-HSQ | 3.0 | 300 |
| CVD-DLC | 2.5-3.0 | 10 |
| CVD-FSG | 3.7 | 5 |
| CVD-SiN | 7-8 | 1 |

From review of the data in Table I, it is clear that an operative invention in accord with the present invention may be effected within the context of the exemplary fluorine containing plasma etch method while employing when forming a patterned first dielectric layer a [hydrogenated diamond like carbon DLC dielectric material or a fluorosilicate glass (FSG) dielectric material, and while similarly employing when forming a blanket second dielectric layer fluorinated polyarylene ether (FLARE) dielectric material or a hydrogen silsesquioxane (HSQ) dielectric material. In accord with the examples of the present invention, determination of additional dielectric materials and plasma etchant materials combinations would also not require undue experimentation.

As is understood by a person skilled in the art, the preferred embodiment and examples of the present invention are illustrative of the present invention rather than limiting of the present invention. Revisions and modifications may be made to methods, materials, structures, and dimensions through which may be practiced the preferred embodiment and examples of the present invention while still providing embodiments and examples of the present invention, further in accord with the appended claims.

What is claimed is:

1. A method for forming an aperture through a dielectric layer comprising:
providing a substrate;
forming upon the substrate a patterned first dielectric layer formed of a first dielectric material having a first dielectric constant of less than about 4.0, the patterned first dielectric layer defining a via;
forming upon the patterned first dielectric layer and filling the via a blanket second dielectric layer formed of a second dielectric material having a second dielectric constant of less than about 4.0;
forming over the blanket second dielectric layer a patterned mask layer which defines the location of a trench to be formed through the blanket second dielectric layer, where an areal dimension of the trench is greater than and at least in part overlapping an areal dimension of the via; and
etching, while employing the patterned mask layer in conjunction with an anisotropic etch method, the blanket second dielectric layer to form an aperture comprising:
the trench; and
at least a portion of the via, where the patterned first dielectric layer provides an intrinsic etch stop within the anisotropic etch method.

2. The method of claim 1 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

3. The method of claim 1 wherein the patterned first dielectric layer and the blanket second dielectric layer are each formed from a separate dielectric material selected from the group consisting of spin-on-polymer (SOP) dielectric materials, spin-on-glass (SOG) dielectric materials, amorphous carbon dielectric materials, diamond like carbon dielectric materials, carbonaceous silicate glass (CSG) dielectric materials, fluorosilicate glass (FSG) dielectric materials and aerogel dielectric materials.

4. The method of claim 1 wherein there is not formed an extrinsic hard mask layer interposed between the patterned first dielectric layer and the blanket second dielectric layer.

5. The method of claim 1 wherein the patterned first dielectric layer is formed to a thickness of from about 4000 to about 10000 angstroms.

6. The method of claim 1 wherein the blanket second dielectric layer is formed to a thickness of from about 4000 to about 7000 angstroms.

7. The method of claim 1 wherein the patterned mask layer is selected from the group consisting of patterned photoresist mask layers and patterned hard mask layers.

8. A method for forming a patterned conductor layer within an aperture through a dielectric layer comprising:
providing a substrate;
forming upon the substrate a patterned first dielectric layer formed of a first dielectric material having a first dielectric constant of less than about 4.0, the patterned first dielectric layer defining a via;
forming upon the patterned first dielectric layer and filling the via a blanket second dielectric layer formed of a second dielectric material having a second dielectric constant of less than about 4.0;
forming over the blanket second dielectric layer a patterned mask layer which defines the location of a trench to be formed through the blanket second dielectric layer, where an areal dimension of the trench is greater than and at least in part overlapping an areal dimension of the via;
etching, while employing the patterned mask layer in conjunction with an anisotropic etch method, the blanket second dielectric layer to form an aperture comprising:
the trench; and
at least a portion of the via, where the patterned first dielectric layer provides an intrinsic etch stop within the anisotropic etch method; and
forming within the aperture a contiguous patterned conductor interconnect and patterned conductor stud layer.

9. The method of claim 8 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

10. The method of claim 8 wherein the patterned first dielectric layer and the blanket second dielectric layer are each formed from a separate dielectric material selected from the group consisting of spin-on-polymer (SOP) dielectric materials, spin-on-glass (SOG) dielectric materials, amorphous carbon dielectric materials, diamond like carbon dielectric materials, carbonaceous silicate glass (CSG) dielectric materials, fluorosilicate glass (FSG) dielectric materials and aerogel dielectric materials.

11. The method of claim 8 wherein there is not formed an extrinsic hard mask layer interposed between the patterned first dielectric layer and the blanket second dielectric layer.

12. The method of claim 8 wherein the patterned first dielectric layer is formed to a thickness of from about 4000 to about 10000 angstroms.

13. The method of claim 8 wherein the blanket second dielectric layer is formed to a thickness of from about 4000 to about 7000 angstroms.

14. The method of claim 8 wherein the patterned mask layer is selected from the group consisting of patterned photoresist mask layers and patterned hard mask layers.

15. The method of claim 8 wherein the contiguous patterned conductor interconnect and patterned conductor stud layer is formed within the aperture while employing a chemical mechanical polish (CMP) planarizing method.
